(19) United States
(12) Patent Application Publication
(10) Pub. No.: US 2026/0059763 A1
(43) Pub. Date: Feb. 26, 2026

(54) SYSTEMS AND LOW TEMPERATURE METHODS OF FORMING FERROELECTRIC DEVICE ELECTRODES

(71) Applicant: Tokyo Electron Limited, Tokyo (JP)

(72) Inventors: Dina H. Triyoso, Albany, NY (US); Tek Po Rinus Lee, Albany, NY (US); Kenichi Imakita, Albany, NY (US); Sara Otsuki, Albany, NY (US)

(21) Appl. No.: 18/812,160

(22) Filed: Aug. 22, 2024

(51) Int. Cl. H10B 53/30

(52) U.S. Cl. CPC H10B 53/30

(57) ABSTRACT

A method of forming an electronic device includes forming a first metal electrode layer over a substrate, the first metal electrode layer including a first metal; forming an electrically ordered material layer over the first metal electrode layer; depositing a second metal over the electrically ordered material layer under cryogenic conditions to form a second metal electrode layer; and patterning the first metal electrode layer, the electrically ordered material layer, and the second metal electrode layer.

### TECHNICAL FIELD

This application relates generally to systems and methods of forming electronic devices, and, in particular embodiments, to systems and methods of forming electronic devices incorporating ferroelectric materials.

### BACKGROUND

Unlike conventional dielectrics, ferroelectric materials exhibit nonlinear polarization in response to an applied electric field E and retain a characteristic net polarization—the remanent polarization, Pᵣ—even in the field's absence. When a sufficiently strong field is applied in opposition to Pᵣ, the polarization state of the ferroelectric switches, and the ferroelectric will then retain polarization—Pᵣ. As a result, ferroelectric materials fulfill the basic criteria for constructing nonvolatile memory by providing a physical implementation of a bit (two distinct polarization states) that does not require refreshing.

The polarization properties of ferroelectric materials emerge from electrical ordering of dipole moments within microscopic domains, and in particular from alignment of the dipole moments. (Any given domain may have a polarization aligned with or against the electric field E. The bulk polarization is determined by the numbers, sizes, and polarizations of the domains.) By contrast, antiferroelectric materials comprise domains with dipole moments of alternating sign, such that these materials have vanishing remanent polarization. Because a sufficiently strong applied field E may nevertheless force the dipole moments to change from an anti-aligned to an aligned arrangement, antiferroelectrics still exhibit pronounced nonlinear polarization and high maximum (or saturation) polarizations Pₛ.

Because antiferroelectrics and ferroelectrics alike have high dielectric constants (low capacitance equivalent thicknesses, CETs), they are attractive materials for the design and fabrication of compact, low-power devices. Antiferroelectrics may replace conventional dielectrics in supercapacitors, for example. Replacing conventional dielectrics with ferroelectrics yields ferroelectric random-access memory (FeRAM), ferroelectric tunnel junctions (FTJs), and ferroelectric or negative-capacitance field-effect transistors (FeFETs or NCFETs), among other conceivable devices. Ferroelectrics and antiferroelectrics may not only serve as drop-in replacements for conventional dielectrics, but their unique electrical properties may substantially improve the performance of some devices. For example, FTJs have giant tunneling resistances modulated by the ferroelectric polarization state, with OFF/ON resistance ratios as high as 10^{4.}

One of the barriers to wider adoption of ferroelectric devices in commercial products, and specifically for memory devices, is an asymmetry in their read-write properties: Ferroelectric memories have nearly unlimited durability to read operations, but they exhibit relatively rapid fatigue and eventual breakdown when written. Fatigue in ferroelectrics is characterized by incremental reductions in the magnitude of Pᵣ that eventually compromise the distinguishability of the polarization states and lead to soft errors. In some instances, fatigue may measurably affect device properties (such as threshold voltages in a FeFET) within as few as 10³ read-write cycles. As such, there is significant interest in improving the durability of ferroelectric devices.

### SUMMARY

In an embodiment, a method of forming an electronic device includes forming a first metal electrode layer over a substrate, the first metal electrode layer including a first metal; forming an electrically ordered material layer over the first metal electrode layer; depositing a second metal over the electrically ordered material layer under cryogenic conditions to form a second metal electrode layer; and patterning the first metal electrode layer, the electrically ordered material layer, and the second metal electrode layer.

In another embodiment, a method of forming an electronic device includes forming a first metal electrode layer over a substrate, the first metal electrode layer including a first metal; forming an electrically ordered material layer over the first metal electrode layer; loading the substrate over a substrate holder disposed in a processing chamber; while cooling the substrate holder, depositing a second metal over the electrically ordered material layer to form a second metal electrode layer; and patterning the first metal electrode layer, the electrically ordered material layer, and the second metal electrode layer.

In still another embodiment, a method of forming an electronic device includes loading a substrate into a first chamber of a cluster tool; depositing, within the first chamber, a first metal onto the substrate to form a first metal electrode layer over the substrate; moving the substrate into a second chamber of the cluster tool; depositing, within the second chamber, an electrically ordered material layer over the first metal electrode layer; moving the substrate into a third chamber of the cluster tool; and depositing, within the third chamber, a second metal over the electrically ordered material layer under cryogenic conditions to form a second metal electrode layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A-1D illustrate cross-sectional views of the formation of a ferroelectric capacitor with one or more components having been deposited onto a cooled surface, followed by formation of a contact via to an electrode of the capacitor, in accordance with various embodiments;

FIG. 2A-2D provide complementary top-down views of the formation of a ferroelectric capacitor with one or more components having been deposited onto a cooled surface, followed by formation of a contact via to an electrode of the capacitor, in accordance with various embodiments;

FIG. 3 is a flow chart for a method of forming an electronic device, such as a ferroelectric capacitor comprising an electrode having been deposited under cryogenic conditions, according to various embodiments;

FIG. 4 provides a conceptual illustration of a voltage-polarization hysteresis loop for a ferroelectric capacitor comprising an electrode having been deposited onto a cooled surface, according to various embodiments, emphasizing expected reductions in the remanent polarization and coercive voltage relative to similar devices formed by conventional methods;

FIG. 5 is a flow chart for a method of forming an electronic device, such as a ferroelectric capacitor comprising an electrode having been deposited onto a substrate disposed over a cooled substrate holder, according to various embodiments;

FIG. 6 provides a cross-sectional schematic view of an atomic layer deposition (ALD) apparatus for the formation of material layers, such as ferroelectric or antiferroelectric material layers, from precursor gases pulsed over a substrate disposed over a heated substrate holder, in accordance with embodiments;

FIGS. 7A and 7B illustrate cross-sectional schematic views of physical vapor deposition (PVD) apparatus using (respectively) capacitively coupled plasma and inductively coupled plasma to sputter metal from a metal target onto a substrate disposed over a cooled substrate holder, and potentially also to provide a portion of one or more process gases to the substrate, in accordance with various embodiments;

FIG. 8 is a flow chart for a method of forming an electronic device, and in particular for using a cluster tool to form an electronic device, such as a ferroelectric capacitor comprising an electrode having been deposited under cryogenic conditions, according to various embodiments; and

FIG. 9 presents a schematic diagram of a cluster tool allowing successive deposition processes to be carried out within a single system comprising multiple process chambers connected by intermediary chambers and airlocks.

### DETAILED DESCRIPTION OF ILLUSTRATIVE EMBODIMENTS

Pristine ferroelectric materials often have a small remanent polarization that grows over repeated read-write cycling, a phenomenon called “wake-up. ” With continued use, Pᵣ reaches a peak and then begins to decrease again, signaling the onset of fatigue. Fatigue eventually comes to an end when the device breaks down entirely.

Wake-up, fatigue, and breakdown stem from the same microscopic origin, namely, a field-modulated aging or ripening of the structure of the ferroelectric. These phenomena may be explained with reference to a specific ferroelectric material, such as hafnium zirconium oxide (HZO).

HZO materials have a continuum of possible formulas HfₓZr₁₋ₓO₂ (0≤x≤1), with HfO₂ (hafnia, x=1) and other hafnium-rich compositions being conventional dielectrics; compositions with x≈0.5 (i.e., near-equal amounts of hafnium and zirconium) being ferroelectric; and zirconium-rich compositions and ZrO₂ (zirconia, x=0) being antiferroelectric, with a vanishing polarization at zero field. The properties of HZO may be tuned both by the choice of x and by doping with metals (such as aluminum, silicon, scandium, yttrium, niobium, lanthanum, or erbium) or non-metals (such as hydrogen, carbon, or nitrogen).

Ferroelectricity and antiferroelectricity in these latter HZO compositions originate in a bistability of their crystal structures. Below a critical temperature T_{c}, and in the absence of an electric field, two different arrangements of oxygens relative to the metal atoms are stable and energetically equivalent. When a field is applied, however, partial charges on each atom interact with the electric field to break this energetic symmetry, and one or the other arrangement (and the corresponding sign of a local dipole moment) will be preferred. Additional lattice-modulated interactions among these local dipoles lead to the formation of regions of predictable electrical ordering known as domains.

In ferroelectric materials, all of the local dipoles within a given domain are aligned with each other and may further align with or oppose an applied field. The remanent polarization Pᵣ or −Pᵣ may thus be attributed to the establishment of energetically stable arrangements (polarization states) in which domains of one alignment dominate in number and/or size. Switching between these states may be accomplished by applying a field opposed to the remanent polarization with a voltage above a certain critical magnitude known as the coercive voltage V_{c}.

As the strength of an applied field increases—and as more anti-aligned dipoles flip direction in order to minimize the energy of the ferroelectric—the polarization increases nonlinearly. For sufficiently high fields, domains comprising anti-aligned dipoles become negligible both in number and size, and the only way to increase the polarization within the ferroelectric is to increase the magnitude of the local dipoles. At this stage, the polarization saturates and changes linearly. Taken together, these phenomena account for the high dielectric constant of ferroelectric materials.

In antiferroelectric materials, by contrast, lattice-dipole interactions favor anti-alignment of the local dipoles within a domain. This alternating pattern leads to a negligible overall polarization of the material in the absence of an applied field. The relationship between field-induced changes in domain structure and the polarization of antiferroelectrics is not well-understood. Nevertheless, it is clear that the vast majority of dipoles will be aligned at saturation, as in ferroelectrics; and antiferroelectric materials also have high dielectric constants.

Electrically ordered materials like ferroelectrics and antiferroelectrics are also piezoelectric, exhibiting an electrical response when under mechanical strain and responding mechanically when a field is applied. The electromechanical properties of a piezoelectric material depend in part on the distribution of grain sizes and—of particular relevance for electronic devices—on the distribution of grain orientations with respect to an applied field. Thus, the grain structure of a material like HZO may be engineered to improve device characteristics.

HZO films typically comprise a mixture of grains corresponding to three distinct phases: an antiferroelectric tetragonal (t) phase, a ferroelectric orthorhombic (o) phase, and a paraelectric monoclinic (m) phase. (Paraelectric materials have nonlinear polarization behavior when a field is applied but no remanent polarization and no microscopic ordering of local dipoles. They are of no use for memory applications but may be useful for energy storage devices like supercapacitors.) The t-and o-phases interconvert relatively freely, with the o-phase being slightly preferred for grains of larger size. Both t-and o-phases are significantly less stable than the m-phase as grains grow, but a large activation barrier tends to suppress interconversion—at least, as long as energy is not introduced into the system in the form of elevated temperatures or fields. In other words, read-write cycles provide energy that facilitates conversion of the t-phase to the o-phase and (ultimately) to the m-phase, degrading the ferroelectric properties of the HZO material.

HZO films may be deposited and annealed over (or while capped by) an electrode material with an incommensurate structure (i.e., with a mismatched or misaligned lattice), such as tungsten or titanium nitride. Strain generated at the boundary between HZO and an incommensurate electrode material due to thermal expansion during annealing favors the formation of grains of the t-and o-phases, tending to make a film more antiferroelectric. With repeated read-write cycling, the (initially relatively small) grains may fuse, and larger grains of the t-phase may convert to the o-phase. Both processes tend to make the film more uniformly ferroelectric and to increase the remanent polarization. While some grains of the o-phase may also convert irrecoverably to the paraelectric m-phase, there will be a net improvement in device properties during this wake-up period.

As cycling continues, the t-phase may be exhausted, and o-phase grains may further convert to the m-phase. At some point, the net effect of these processes will be to reduce the remanent polarization irreversibly, if only minutely over any given cycle. This fatigue period continues until the device breaks down.

In addition to varying numbers and sizes of t-, o-, and m-phase grains, an HZO film may also initially have a deposition process-determined concentration of defects, particularly oxygen vacancies with a +2 charge (V_{O}²⁺). The presence of these vacancies encourages the formation of t-phase grains when HZO films are deposited, extending the wake-up period. For this reason, and in accordance with various embodiments, HZO films may be deposited by a process such as atomic layer deposition (ALD) with a timed dose of an oxidant, such as water, which tends to increase the concentration of vacancies.

Over many read-write cycles, however, oxygen vacancies are believed to be the cause of breakdown. Like other types of defects, V_{O}²⁺ accumulates at grain boundaries within a film and at its surface. As the film ages and grains of the stable m-phase grow, V_{O}²⁺ may form a continuous path from one surface of the film to the other along m-phase grain boundaries, forming a leakage path that shorts the device.

The inventors have observed that depositing an electrode material over a substrate held at a temperature T_{sub} below the melting point of the electrode material, Tₘ, may modify the material's properties. For example, the resistivity of the material may reliably decrease (or increase) as T_{sub} decreases. Similarly, the orientation of the material may improve as T_{sub} decreases, as evidenced by a smaller number of peaks in an X-ray diffraction measurement. The smoothness of the surface may also improve, corresponding to higher intensities in X-ray reflectivity measurements and lower average surface roughness Rₐ.

Embodiments improve the grain structure of an incommensurate electrode material deposited over an electrically ordered material (whether ferroelectric or antiferroelectric) by executing the deposition at low temperatures (from room temperature down to cryogenic temperatures in the tens of Kelvin). As a result, embodiments improve the grain structure of the electrically ordered material itself. In particular, and in accordance with various embodiments, a smoother and finer-grained electrode material may contribute on annealing to the formation of smaller and better-oriented grains within the electrically ordered material. Consequently, embodiments enable the fabrication of electronic devices with numerous advantages.

Smaller grain sizes correspond with greater uniformity in both the electrode and the electrically ordered working material of a device, improving scalability and enabling high-density storage devices. With reference to HZO films specifically, and in accordance with various embodiments, smaller grains favor the antiferroelectric t-phase and may extend the wake-up period. Moreover, smaller grains may forestall breakdown by requiring a greater number of switching cycles to fuse and form the large grains whose boundaries support the formation of leakage paths. Changes in electrode material enabled by embodiments may also lead to a net increase in remanent polarization, improving ferroelectric implementations of a physical bit, while reducing the coercive voltage (and thus the power consumption) relative to a conventionally fabricated device.

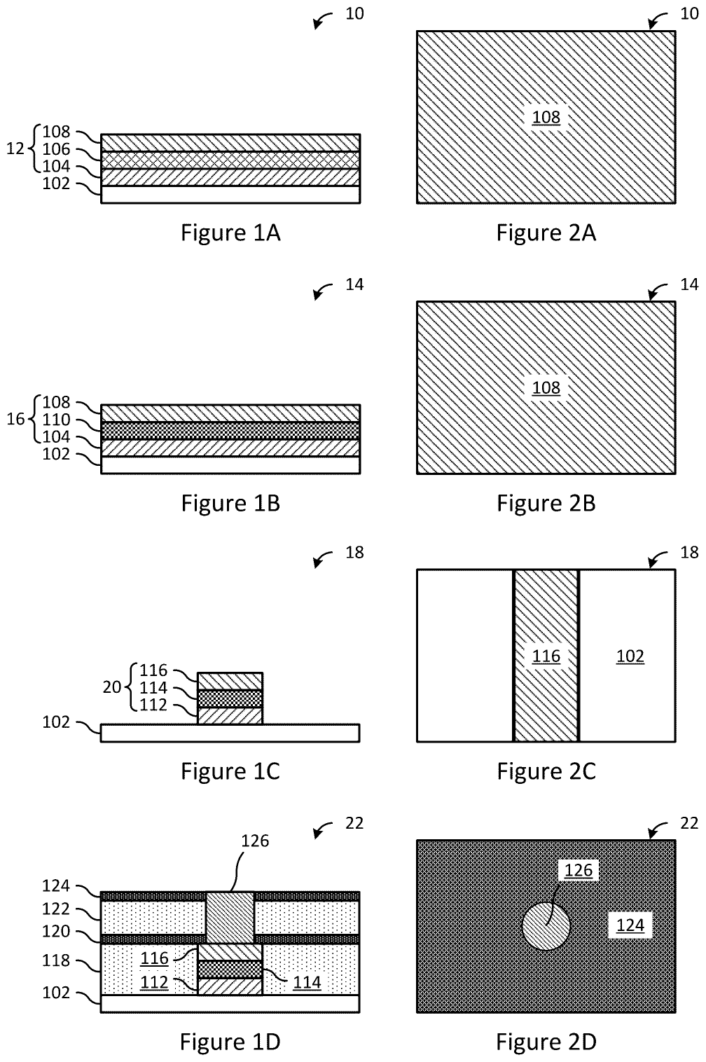

With reference now to the drawings, FIG. 1A-1D and 2A-2D respectively depict cross-sectional and top-down views of the formation of a ferroelectric capacitor, in accordance with embodiments of the present application. Like reference numerals are used to refer to identical features in the two figures.

FIGS. 1A and 2A depict a workpiece 10 comprising a layer stack 12 disposed over a substrate 102. (The layer stack 12 itself comprises a first metal electrode layer 104, an electrically ordered material layer 106, and a second metal electrode layer 108.) In FIGS. 1B and 2B, the electrically ordered material layer 106 has been annealed to form an annealed electrically ordered material layer 110. FIGS. 1C and 2C illustrate the device after the layers have been patterned and etched to define a (linear) capacitor 18. Finally, FIGS. 1D and 2D depict the device after two rounds of deposition of interlayer dielectrics and etch stop layers, followed by formation of a contact via 126. This sequence of steps demonstrates the transformation of the initial layer stack 12 into a functional capacitor 18 that may further be formed into a device 22 within a larger semiconductor device, according to various embodiments.

The substrate 102 represents generically any suitable semiconductor substrate being processed in accordance with embodiments of the present invention. The substrate 102 may be a bulk substrate such as a blank silicon wafer, a silicon-on-insulator (SOI) wafer, or any of various other semiconductor substrates. The substrate 102 may also be coated or layered with any number of additional materials, including compound semiconductors, metal or metalloid oxides, or metal or metalloid nitrides. The substrate 102 may include any material portion or structure of a device, particularly a semiconductor or other electronics device. Similarly, in some embodiments, the substrate 102 may itself be patterned or embedded in other components of a semiconductor structure or device, such as a reconstituted wafer in a wafer-level package process.

A first metal electrode layer 104 may be formed over the substrate 102. (The first metal electrode layer 104 may also be referred to as a bottom electrode layer 104, reflecting its position in various embodiments.) The first metal electrode layer 104 may cover a portion (or all) of the substrate 102.

In various embodiments, the first metal electrode layer 104 may comprise a first metal, such as aluminum, titanium, cobalt, nickel, copper, molybdenum, ruthenium, tantalum, tungsten, iridium, or platinum. The first metal electrode layer 104 may comprise any suitable conductive material, including the first metal in elemental form; conductive nitrides such as titanium nitride, or tantalum nitride; or conductive oxides such as tungsten oxide, iridium(IV) oxide, ruthenium(IV) oxide, lanthanum strontium cobalt oxide (LSCO), strontium ruthenium oxide (SRO), or lanthanum-doped SRO, according to various embodiments.

The first metal electrode layer 104 may be deposited using any suitable deposition technique. For example, the layer may be formed using physical vapor deposition (PVD) methods such as sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; or any other layer deposition process or combination thereof. In some embodiments, the first metal electrode layer 104 may be formed by depositing the first metal over the substrate 102 while holding a temperature T_{sub} of the substrate 102 between 70 K and 293 K, using similar techniques and process conditions as described below for the second metal electrode layer 108. A thickness of the first metal electrode layer 104 may be between 5 nm and 100 nm, according to various embodiments.

An electrically ordered material layer 106 may then be formed over the first metal electrode layer 104. The electrically ordered material layer 106 may comprise a ferroelectric material or an antiferroelectric material, according to various embodiments. In some embodiments, the electrically ordered material layer 106 may comprise HZO, with or without doping and in any of the antiferroelectric or ferroelectric compositions previously described. In other embodiments, the electrically ordered material layer 106 may comprise a perovskite, such as lithium niobate, barium titanate, bismuth ferrite, lead zirconate titanate (PZT), or lead magnesium niobate-lead titanate (PMN-PT); a layered perovskite such as strontium bismuth tantalate; a wurtzite, such as aluminum scandium nitride, aluminum boron nitride, or zinc magnesium oxide; or another compound, such as indium(III) selenide. In some embodiments, the electrically ordered material layer 106 may comprise a bilayer or multi-layer structure; in certain of these latter embodiments, two or more layers may have the same elemental composition but different stoichiometry.

The electrically ordered material layer 106 may be deposited using any suitable deposition technique, such as ALD, PVD, sol-gel deposition, CVD, or any other layer deposition process or combination thereof. A thickness of the electrically ordered material layer 106 may be between 1 nm and 20 nm, according to various embodiments.

In some embodiments, the electrically ordered material layer 106 may exhibit bulk electrical ordering (show voltage-polarization hysteresis consistent with ferroelectricity or antiferroelectricity) to some extent after it has been deposited. In other embodiments, depending on composition, stoichiometry, and method and conditions of deposition, the layer deposited may instead be a material layer capable of forming an electrically ordered material layer 106 subsequent to further processing. In some such embodiments, the material layer deposited may be an amorphous layer that crystallizes when annealed (using any of the methods described below) to yield a microscopic structure exhibiting bulk electrical ordering, i.e., an annealed electrically ordered material layer 110.

As depicted in both FIGS. 1A and 2A, a second metal electrode layer 108 may be formed over the electrically ordered material layer 106. (The second metal electrode layer 108 may also be referred to as a top electrode layer 108, reflecting its position in various embodiments.) In some embodiments (but not as illustrated), the second metal electrode layer 108 may be patterned to cover a smaller area than the underlying layers, facilitating the eventual formation of distinct top and bottom contacts.

In various embodiments, the second metal electrode layer 108 may be formed by depositing a second metal over the electrically ordered material layer 106 while holding a temperature T_{sub} of the substrate 102 (and the layers disposed above it) between 70 K and 293 K. According to various embodiments, this temperature control may be achieved by loading the substrate over a substrate holder coupled to a cooler configured to establish and maintain temperatures within the target range. In some embodiments, the substrate holder may thus be a cooled chuck or a cryogenic chuck.

In certain embodiments, T_{sub} may be held between 70 K and 125 K, corresponding to cryogenic conditions achievable using (for example) liquid nitrogen or liquid krypton. In other such embodiments, the cryogenic conditions may comprise T_{sub} between 125 K and 170 K, corresponding to refrigeration with “high-temperature” cryogenic liquids, such as liquid xenon or liquid ethylene. In still other embodiments, the cryogenic conditions may comprise T_{sub} between 70 K and 170 K. Some embodiments may further comprise T_{sub} between 170 K and 293 K, achievable by conventional refrigeration or deep-freezing techniques.

The second metal and the second metal electrode layer 108 may comprise any of the elements or compounds suitable for the first metal or first metal electrode layer 104, respectively. For example, the second metal may include aluminum, titanium, nickel, molybdenum, ruthenium, tantalum, tungsten, iridium, or platinum. The second metal electrode layer 108 may comprise the second metal in elemental form, conductive nitrides, or conductive oxides, similar to those described for the first metal electrode layer 104. In some embodiments, the second metal and the first metal may be the same metal.

In some embodiments, the second metal electrode layer 108 may be formed using PVD. In other embodiments, any of the aforementioned deposition techniques, or combinations thereof, may be employed to form the second metal electrode layer 108. A thickness of the second metal electrode layer 108 may be between 2 nm and 100 nm, according to various embodiments.

Subsequent to deposition of the second metal electrode layer 108 under cooled or cryogenic conditions, according to various embodiments, the workpiece 10 of FIGS. 1A and 2A may be in place. In some embodiments, the workpiece 10 may be allowed to return to ambient temperature by passive equilibration; in other embodiments, the workpiece 10 may be partially or fully warmed by active use of a hot plate or other heater in preparation for further processing.

One such processing step, according to embodiments, may be annealing of the workpiece 10 to form an annealed workpiece 14, and specifically annealing of the electrically ordered material layer 106 to form an annealed electrically ordered material layer 110 in an annealed stack 16. At the macroscopic level, and as illustrated in FIGS. 1B and 2B, the workpiece 10 may look nearly identical. Microscopic changes in the structure of the annealed electrically ordered material layer 110 may be significant for device properties, however, meriting a change in pattern fill.

Annealing methods may include rapid thermal processing, furnace annealing, or other annealing methods consistent with a thermal budget for the respective embodiments. In various embodiments, a rapid thermal process may be performed at temperatures between 400° C. and 550° C. for a duration between 1 and 600 seconds. In a particular embodiment, the rapid thermal process may be performed at 500° C. for 30 seconds. In another embodiment, furnace annealing may be applied, with the workpiece 10 heated at 400° C. for 1 hour. Still other embodiments may use annealing methods such as microwave annealing at 2.45 GHz and between 500 W and 3 kW of power for 30 seconds to 5 minutes or RF annealing at 13.56 MHz between 100 W and 1 kW of power for 10 seconds to 2 minutes. Some embodiments may use E-field annealing with a field strength between 1 MV/cm to 10 MV/cm for 5 seconds to 600 seconds, the duration of the annealing being divided among electric field pulses with duration between 1 ms and 100 ms.

Annealing may reform the structure of the electrically ordered material layer 106 to yield an annealed electrically ordered material layer 110 with improved homogeneity, grain structure, remanent polarization, and/or other characteristics. Advantageously, annealing of the electrically ordered material layer 106 in contact with the smoother, finer-grained surface of the second metal electrode layer 108 as deposited under cooled or cryogenic conditions (according to the respective embodiments) may have a superior templating effect, inducing more salutary changes in the annealed electrically ordered material layer 110.

While not being tied to any specific theory, in embodiments comprising an electrically ordered material layer 106 comprising HZO, annealing in contact with such a second metal electrode layer 108 may encourage the formation of smaller grains and a larger fraction of antiferroelectric t-phase grains during annealing. In embodiments producing a memory device, such a change may extend the wake-up period and forestall breakdown. In other embodiments, associated changes in the voltage-polarization hysteresis of a resulting device may include power-saving reductions in the coercive voltage relative to devices formed with a non-cryogenically deposited second metal electrode layer 108.

With reference to FIGS. 1C and 2C, the annealed stack 16 may be patterned and etched to form a capacitor 18, which may be (in particular embodiments) a capacitor. Patterning may be performed using any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, high numerical aperture EUV (high NA-EUV), or deep UV (DUV) lithography. Following the lithography, any anisotropic etching method, such as reactive ion etching, may be used to form the patterned stack 20.

Patterning and etching may result in the formation of distinct structural components within the patterned stack 20. In particular, and as shown in FIG. 1C, the patterned stack 20 may comprise a first metal electrode (or bottom electrode) 112, a patterned electrically ordered material layer 114, and a second metal electrode (or top electrode) 116. A width (e.g., a critical dimension) of the patterned stack 20 may be between 30 nm and 300 nm, in various embodiments. In some embodiments, the critical dimension may be between 30 nm and 60 nm. In embodiments (not illustrated) for which a single capacitor or a line of separate capacitors may be desirable, additional patterning and etching may be carried out.

Further process steps may form a contact via 126 over the capacitor 18, resulting in the device 22 illustrated in FIGS. 1D and 2D. Formation of the contact via 126 may proceed (in various embodiments) by any conventional method; possibilities corresponding to various embodiments are briefly outlined below.

A first interlayer dielectric 118 may be deposited over the capacitor 18. The first interlayer dielectric 118 may comprise silicon oxide, silicon nitride, silicon oxynitride, or another high-k dielectric material, in various embodiments. Alternatively, the first interlayer dielectric 118 may comprise a low-k dielectric material such as organo-or fluorosilicate glass, a porous dielectric such as black diamond (BD1, BD2, or BD3 forms of SiOC:H), or a polymer dielectric. The first interlayer dielectric 118 may be deposited using any suitable deposition technique, such as metal-organic CVD using tetraethyl orthosilicate (TEOS) in the case of silicon oxide.

Following the deposition of the first interlayer dielectric 118, a first etch stop layer 120, a second interlayer dielectric 122, and a second etch stop layer 124 may be sequentially deposited. The etch stop layers 120 and 124 may comprise any suitable material, such as silicon nitride, while the second interlayer dielectric 122 may comprise any of the materials described for the first interlayer dielectric 118. These layers may be deposited using any suitable deposition techniques, similar to those used for previous layers.

A channel may then be patterned and etched sequentially through the first etch stop layer 120, the second interlayer dielectric 122, and the second etch stop layer 124 to form a channel revealing an upper surface of the top electrode 116. (While a cross section of the channel illustrated in FIG. 2D is circular, any desirable shape may be patterned and etched in a given embodiment.) Patterning techniques used may include any lithographic technique described above.

The first and second etch stop layers 120 and 124 may be etched by wet etching (or other isotropic etching method) with a chemistry selective toward these layers. In some embodiments, the wet etch chemistry may comprise hot phosphoric acid. The second interlayer dielectric 122 may be etched by an anisotropic etching method such as reactive ion etching, according to an embodiment.

A contact material may next be deposited by any suitable method to fill the channel and further to cover an upper surface of the second etch stop layer 124. The contact material may be any appropriate metallization element, such as any of the electrode materials described previously. The contact material may then be planarized to form the contact via 126, completing the device 22.

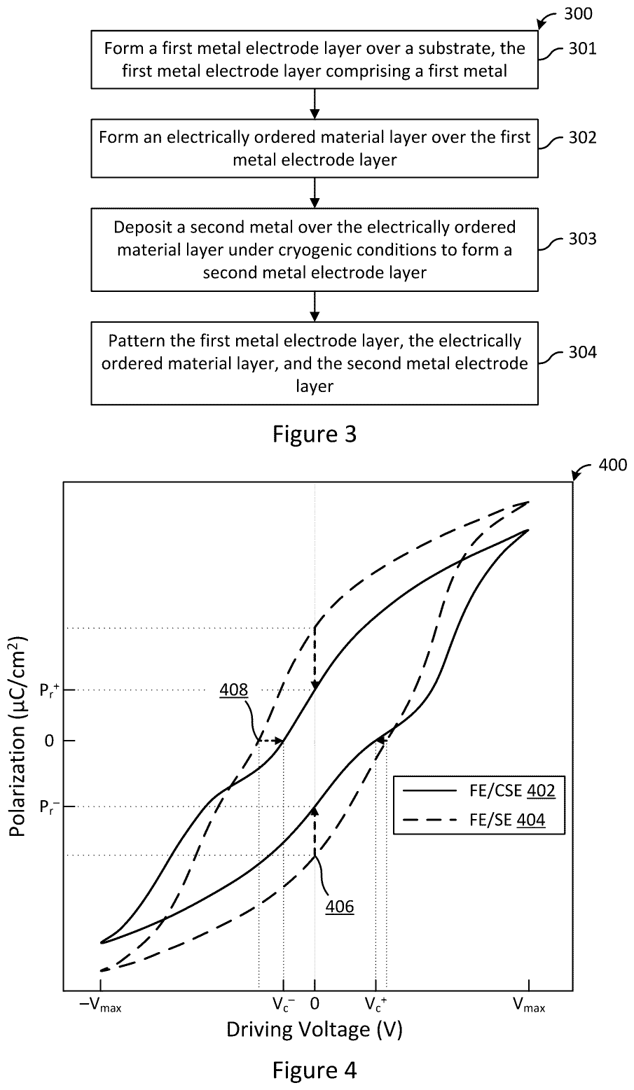

The process flow described with reference to FIG. 1A-1D and 2A-2D may represent various embodiments of a more general method 300 of forming an electronic device, as illustrated by a flow chart in FIG. 3.

In box 301, a first metal electrode layer is formed over a substrate, the first metal electrode layer comprising a first metal. (In some embodiments, the first metal electrode layer may be formed by deposition of a first metal over the substrate under cryogenic conditions.) Next, in box 302, an electrically ordered material layer is formed over the first metal electrode layer. Third, in box 303, a second metal is deposited over the electrically ordered material layer under cryogenic conditions to form a second metal electrode layer. These steps, taken together, may result in a structure like the layer stack 12 illustrated in FIG. 1A. Some embodiments may further comprise annealing the electrically ordered material layer before proceeding to box 304.

Box 304 comprises patterning the first metal electrode layer, the electrically ordered material layer, and the second metal electrode layer. In embodiments illustrated by FIGS. 1C and 2C, the result of the patterning may be the capacitor 18 disposed over the substrate 102.

Devices integrating the completed capacitor 18 of FIGS. 1C and 2C or the device 22 of FIGS. 1D and 2D may include, according to various embodiments, FeRAM, FTJs, FeFETs, NCFETs, ferroelectric content-addressable memories (FeCAMs), including ferroelectric ternary CAMs (FeTCAMs), artificial synapses for neuromorphic computing (such as reservoir computing), energy storage devices such as supercapacitors, and other such devices.

FIG. 4 provides a plot 400 depicting anticipated changes in the voltage-polarization hysteresis properties of devices formed according to embodiments of the method 300 relative to structurally similar devices formed without cryogenic deposition of the second metal electrode. The capacitor 18 of FIGS. 1C and 2C may be such a device. Plots similar to plot 400 may be produced by applying an AC driving voltage with magnitude Vₘₐₓ (typically between 1 and 10 V) to the respective devices at a chosen frequency (10 kHz, in one embodiment) and smoothing the measured trajectories in the V-P plane (with polarizations typically in the tens of μC/cm²).

Plot 400 compares an exemplary hysteresis loop for a device formed according to method 300—a device comprising a conventional first metal electrode 112 and a cooled or cryogenically deposited second metal electrode 116, labeled “FE/CSE” hysteresis loop 402—with a corresponding loop for a conventionally formed device, labeled “FE/SE” hysteresis loop 404. Anticipated reductions in the remanent polarization 406 are illustrated by half-dashed arrows and dotted lines extending to the polarization axis from the line with V=0, while reductions in the coercive voltage 408 are illustrated by half-half-dashed arrows and half-dotted lines extending to the voltage axis from the line with P=0. Such reductions have been observed by the inventors for embodiment devices and endow FE/CSE devices with several advantages.

FE/CSE hysteresis loop 402 exhibits a pronounced double hysteresis, as well as an overall inversion asymmetry with respect to the origin in the V-P plane of plot 400. These features of FE/CSE hysteresis loop 402 are characteristic signatures of antiferroelectricity in the (annealed and) patterned electrically ordered material layer 114. Such signatures are not obvious in the FE/SE hysteresis loop 404, indicating that embodiment devices may have an extended wake-up period relative to conventional devices (and thus greater durability).

Asymmetry in the FE/CSE hysteresis loop 402 may originate in part from polarization state-dependent reductions in the remanent polarization 406 and reductions in the coercive voltage 408. (Though not depicted to any significant extent in FIG. 4, some asymmetry may be present in real FE/SE hysteresis loops.) As illustrated, the coercive voltage and remanent polarization of the positive polarization state (respectively V_{c}⁺ and Pᵣ⁺) are reduced by different amounts from the coercive voltage and remanent polarization of the negative polarization state (respectively V_{c}⁻ and Pᵣ⁻). Such asymmetries may be controllable through judicious choice of materials or dopants and with further process development, enabling the production of devices with unusual electrical characteristics.

In any case, reductions in the coercive voltage 408 are advantageous for reducing power consumption in embodiment devices. While reductions in remanent polarization 406 may narrow the memory window in embodiment memory devices, such an effect may be compensated by choosing a second metal (or conductive material containing said second metal) for the second metal electrode layer 108 that would yield somewhat higher remanent polarizations in a conventional FE/SE device. Because coercive voltages are relatively tightly constrained, the overall effect may be advantageous with respect to both device parameters.

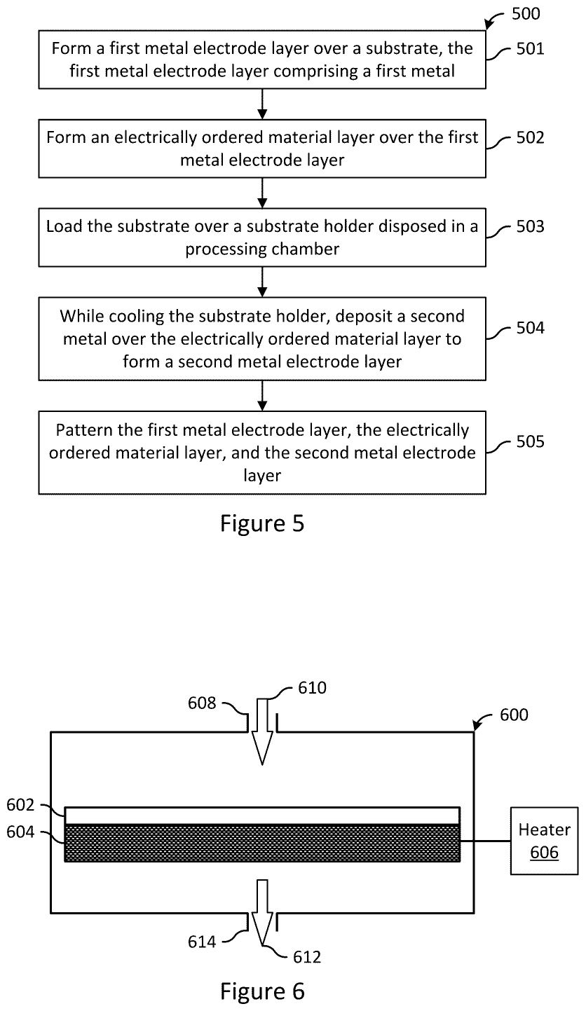

FIG. 5 provides a flow chart of another method 500 of forming an electronic device. The process flow described with reference to FIG. 1A-1D and 2A-2D may represent various embodiments of this method also.

In box 501, a first metal electrode layer is formed over a substrate, the first metal electrode layer comprising a first metal. In some embodiments, the first metal electrode layer may be formed by deposition of a first metal over the substrate under cryogenic conditions. Next, in box 502, an electrically ordered material layer is formed over the first metal electrode layer.

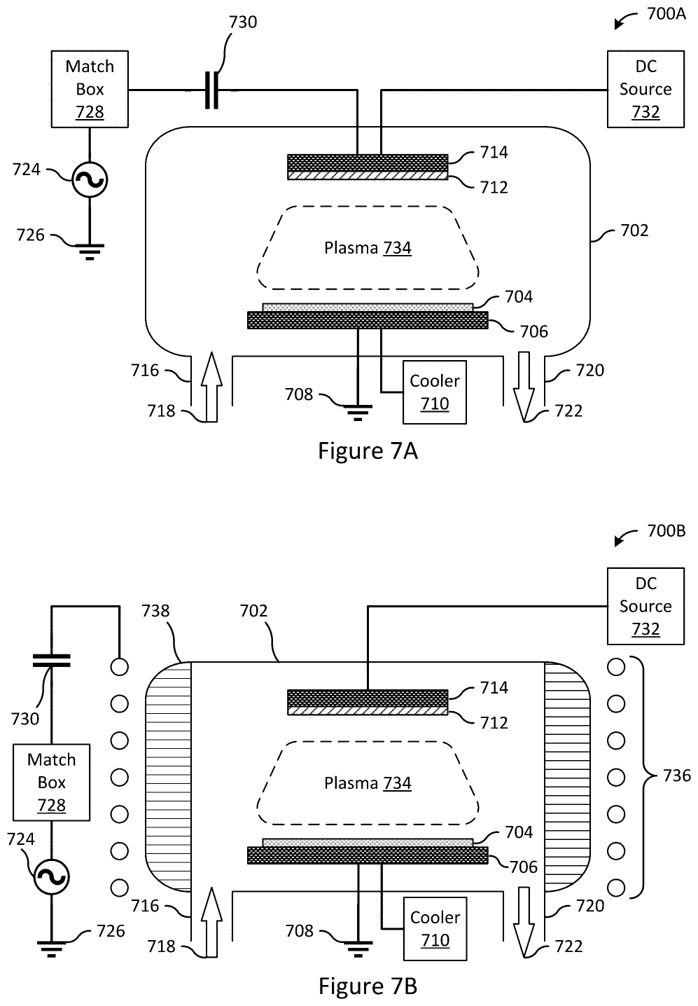

Boxes 503 and 504 specifically concern the conditions under which a second metal electrode layer may be deposited. In box 503, the substrate is loaded over a substrate holder disposed in a processing chamber. The substrate holder is a structural feature of the processing chamber, which may be any suitable deposition chamber as long as the substrate holder is coupled to a cooler configured to establish and maintain temperatures within a target (cooled or cryogenic) range. According to some embodiments, and as will be discussed in more detail with reference to FIG. 7, the processing chamber may be a PVD chamber.

In box 504, while cooling the substrate holder, a second metal is deposited over the electrically ordered material layer to form a second metal electrode layer. Then, in box 505, the first metal electrode layer, the electrically ordered material layer, and the second metal electrode layer are patterned. In embodiments illustrated by FIGS. 1C and 2C, the result of the patterning may be the capacitor 18 disposed over the substrate 102.

Various embodiments of methods 300 and 500 may correspond to the process flow of FIG. 1A-1D, comprising any of a variety of possible deposition techniques and chambers. FIGS. 6 and 7 respectively provide cross-sectional views of exemplary process chambers for ALD and for PVD, the PVD chamber comprising a substrate holder configured to establish and maintain temperatures within a target (cooled or cryogenic) range.

In an ALD chamber 600, a substrate 602 is loaded over a substrate holder 604. The ALD chamber 600 comprises a heater 606 (comprising resistive or inductive heating elements, thermocouples, control circuitry, etc.) coupled to the substrate holder 604 in order to establish and maintain the elevated temperatures appropriate for atomic layer deposition over the substrate 602. In some embodiments, the temperature range may be between 100° C. and 600° C. In other embodiments, the temperature range may be between 100° C. and 400° C.

Precursor gases and purge gases may be introduced into the chamber through a gas inlet 608, which may be preceded (in some embodiments not illustrated here) by a mixer combining flows of two or more precursor or purge gases from separate gas lines. In some embodiments, the gas inlet may be a showerhead helping to ensure uniform flow of gas over the entire surface of the substrate 602. The gas flow, indicated by an in-flow 610, passes over the heated substrate 602; precursor molecules may then react at the surface of the substrate 602 to form the desired material layer. Excess precursors and reaction byproducts are removed from the surface of the substrate 602 by subsequent in-flow 610 of one or more purge gases, typically comprising an inert gas such as N₂. The mixed precursors, byproducts, and purge gas exit the ALD chamber 600 through a gas outlet 614, as indicated by an out-flow 612.

The ALD chamber 600 illustrated in FIG. 6 may correspond to multiple embodiments. In some embodiments, the ALD chamber 600 may be a standalone ALD chamber. In other embodiments, it might represent a single station of a multi-station ALD system. In such a system, the substrate holder 604 may move along a linear track or rotate along a circular path, exposing the substrate 602 to in-flows from several successive or cycled mixtures of precursor or purge gases from different showerheads. Embodiments of this latter type may be advantageous for high-throughput fabrication and for conserving process gases.

In a variety of embodiments, the ALD chamber 600 may be used to form the electrically ordered material layer 106 illustrated in FIG. 1A-1D and 2A-2D. In some embodiments, the electrically ordered material layer 106 may comprise a ferroelectric material; in other embodiments, the electrically ordered material layer 106 may comprise an antiferroelectric material. In still other embodiments, the electrically ordered material layer 106 may comprise a ferrielectric material (comprising interpenetrating ferroelectric lattices with different remanent polarizations), a multiferroic material (combining ferroelectricity with ferromagnetism or ferroelasticity), or another material exhibiting electrical ordering. Embodiments may also comprise an electrically ordered material layer 106 comprising a bilayer or multilayer combining any of the aforementioned types of material, some or all being deposited by ALD.

In certain embodiments, the electrically ordered material layer 106 may comprise any of the continuum of stoichiometries of HZO, and in particular the ferroelectric or antiferroelectic stoichiometries HfₓZr₁₋ₓO₂ with 0≤x≈0.5. In an ALD process for HZO, alternating pulses of hafnium and zirconium precursors may be introduced into the deposition chamber, typically at temperatures between 200° C. and 400° C. and at low pressures, e.g., between 0.1 and 1 torr. Each precursor pulse may be followed by a purge step to remove excess precursors and byproducts; after the precursor pulses, an oxidant pulse introduces oxygen to oxidize the metal surface, followed by a further purge step to remove organics or other byproducts from the surface.

In embodiments, precursors for hafnium may include hafnium tetrachloride (HfCl₄) or a metal-organic compound, such as tetrakis(ethylmethylamido)hafnium(IV) (TEMAH) or tris(dimethylaminocyclopentadienyl)hafnium (HfCp(NMe₂)₃). Analogous precursors for zirconium may include zirconium tetrachloride (ZrCl₄) or a metal-organic compound, such as tetrakis(ethylmethylamido)zirconium(IV) (TEMAZ) or tris(dimethylaminocyclopentadienyl)zirconium (ZrCp(NMe₂)₃). Water vapor, oxygen, or ozone may be used as oxidants in some embodiments.

Because each ALD cycle deposits a sub-monolayer of material, the ALD cycle may be repeated until the desired thickness of the HZO film is achieved. The composition of the HZO film may be controlled by adjusting the number, duration, and other parameters of the hafnium and zirconium precursor pulses. The thickness of the resulting electrically ordered material layer 106 comprising HZO may be between 2 nm and 100 nm, according to various embodiments. In another embodiment, the thickness of the resulting electrically ordered material layer 106 comprising HZO may be between 1 nm and 20 nm.

FIGS. 7A and 7B provides cross-sectional schematic views of PVD apparatus that may be used to form the second metal electrode layer 108 or, in some embodiments, the electrically ordered material layer 106. In particular, FIGS. 7A and 7B respectively illustrate a capacitively coupled PVD apparatus 700A and an inductively coupled PVD apparatus 700B. Both types of apparatus may be configured to deposit the second metal under cooled or cryogenic conditions, according to various embodiments, by way of a lower electrode 706 that serves as a substrate holder (or cooled chuck, or cryogenic chuck) for establishing and maintaining temperatures in the ranges previously described.

With reference to FIG. 7A, the capacitively coupled PVD apparatus 700A may comprise a plasma processing chamber 702 configured with two electrodes: the lower electrode 706 (which, again, may also be referred to as a substrate holder or cryogenic chuck) and an upper electrode 714. In various embodiments, the lower electrode 706 may be configured to hold or support the substrate 704, which may represent (with reference to FIG. 1A) the substrate 102, the workpiece 10, or an intermediate workpiece comprising a subset of layers of the layer stack 12. The lower electrode 706 may incorporate vacuum suction or other means of securing the substrate 704 and ensuring uniform thermal contact.

In various embodiments, the lower electrode 706 may be coupled to a cooler 710 (comprising thermocouples, control circuitry, channels for circulating refrigerants or chilled air, etc.), which may be configured to establish and maintain temperatures within a target range between 70 K and 293 K. In some embodiments, the temperature may be held between 70 K and 125 K, corresponding to cryogenic conditions achievable using a refrigeration system comprising an appropriate working fluid, such as liquid nitrogen or liquid krypton. In other embodiments, the cryogenic conditions may comprise temperatures between 125 K and 170 K, corresponding to refrigeration with high-temperature cryogenic working fluids, such as liquid xenon or liquid ethylene. In still other embodiments, the cryogenic conditions may comprise temperatures between 70 K and 170 K. Some embodiments may further comprise temperatures between 170 K and 293 K, achievable by conventional refrigeration or deep-freezing techniques.

As illustrated in FIG. 7A, the lower electrode 706 may be connected to a ground 708, such that any voltage difference between the lower electrode 706 and the upper electrode 714 may arise from voltages applied to the upper electrode 714. In other embodiments, a separately controllable voltage may be applied to lower electrode 706. In still other embodiments, the ground 708 may be a chassis ground connected to the plasma processing chamber 702, with the lower electrode 706 floating.

The upper electrode 714 is configured to hold or support a metal target 712. The upper electrode 714 may further incorporate heating or cooling elements, temperature controls, vacuum suction, or other means of securing and controlling the physical state of the metal target 712. In some embodiments, the upper electrode 714 may be augmented with permanent magnets in order to perform magnetron sputtering.

Some embodiments may comprise deposition of more than one metal simultaneously or in successive depositions within the same plasma processing chamber 702. For example, embodiments may comprise deposition of a first or second electrode material layer 104 or 108 comprising an alloy, a solid solution, or a layered composite. Other embodiments may comprise deposition of an electrically ordered material layer 106, such as HZO or other aforementioned materials. In some such embodiments, multiple metal targets smaller than the illustrated metal target 712 may be disposed on the upper electrode 714. Alternately, and in respective embodiments, an alloyed metal target 712 may be disposed on the upper electrode 714, or several smaller and similarly configured electrodes may be disposed within the plasma processing chamber 702, each loaded with a separate metal target of appropriate composition.

The plasma processing chamber 702 comprises a gas inlet 716 to permit charging of the chamber with process gases, as indicated by an in-flow 718. (Process gases may comprise, in embodiments, argon carrier gas to be ignited as a plasma 734. In embodiments comprising deposition of a metal-containing compound, process gases may further comprise any convenient gas comprising necessary elements, such as oxygen gas for forming electrically ordered oxides like HZO.) A gas outlet 720 allows for evacuation and pressure control, as indicated by an out-flow 722.

In the capacitively coupled PVD apparatus 700A, an RF power supply 724 may be coupled to the upper electrode 714 through impedance-matching circuitry (match box 728) and a blocking capacitor 730. A DC source 732, comprising a DC power supply and an RF choke, may also be connected to the upper electrode 714 in some embodiments for the purpose of performing DC magnetron sputtering. In any case, the connection between the RF power supply 724 and the upper electrode 714 establishes a voltage difference between the upper electrode 714 and the lower electrode 706, with the upper electrode 714 acting as a cathode.

In order to perform PVD, the plasma processing chamber 702 may be pumped down to high vacuum (between 10⁻⁵ torr and 10⁻⁸ torr, according to embodiments) through the gas outlet 720. Process gases are then introduced through the gas inlet 716 to establish a desired process pressure. In various embodiments, the process pressure may be between 0.25 mtorr and 30 mtorr. In some embodiments, the process pressure may be between 0.5 to 1.0 mtorr. In other embodiments, the process pressure may be between 1 and 10 mtorr. In still other embodiments, the process pressure may be between 10 mtorr and 30 mtorr.

When sufficient voltage is applied within the plasma processing chamber 702, the plasma 734 may be ignited in a carrier gas (such as argon). Ions from the plasma may then be accelerated towards the metal target 712, causing sputtering of metal particles. These particles may then deposit on the substrate 704; in some embodiments, particles comprising atoms of other process gases may also condense onto the substrate 704, providing a portion of those process gases to the surface in order to form a target compound.

The capacitively coupled PVD apparatus 700A and the inductively coupled PVD apparatus 700B operate on similar principles and comprise similar components, according to the respective embodiments. (Like reference numerals are used to label like components.) The principal difference is that, in the inductively coupled PVD apparatus 700B, an RF power supply 724 may be connected to an inductive coil 736 that surrounds the plasma processing chamber 702. Dielectric windows 738 in the inductively coupled PVD apparatus 700B allow the resulting RF field to penetrate the plasma processing chamber 702 and thereby to ignite the plasma 734.

Irrespective of whether sputtering is accomplished using a capacitively coupled plasma or an inductively coupled plasma, the resulting PVD process may be used in respective embodiments to deposit the first or second metal to form the first metal electrode layer 104 or the second metal electrode layer 108. Embodiments comprising deposition of the second metal electrode layer 108 may form the second metal electrode 116 with the improved grain structure and surface smoothness previously mentioned as leading to advantageous properties in the annealed electrically ordered material layer 110. Other embodiments may comprise deposition of the first metal electrode layer 104 and forming the first metal electrode 112 with similarly improved grain structure and surface smoothness.

In still other embodiments, PVD may be used to deposit the electrically ordered material layer 106 at cooled or cryogenic temperature conditions distinct from the elevated temperatures used for ALD (and described with reference to FIG. 6). In various of these latter embodiments, temperature ranges may be between 70 K and 293 K, including any of the more limited ranges described previously.

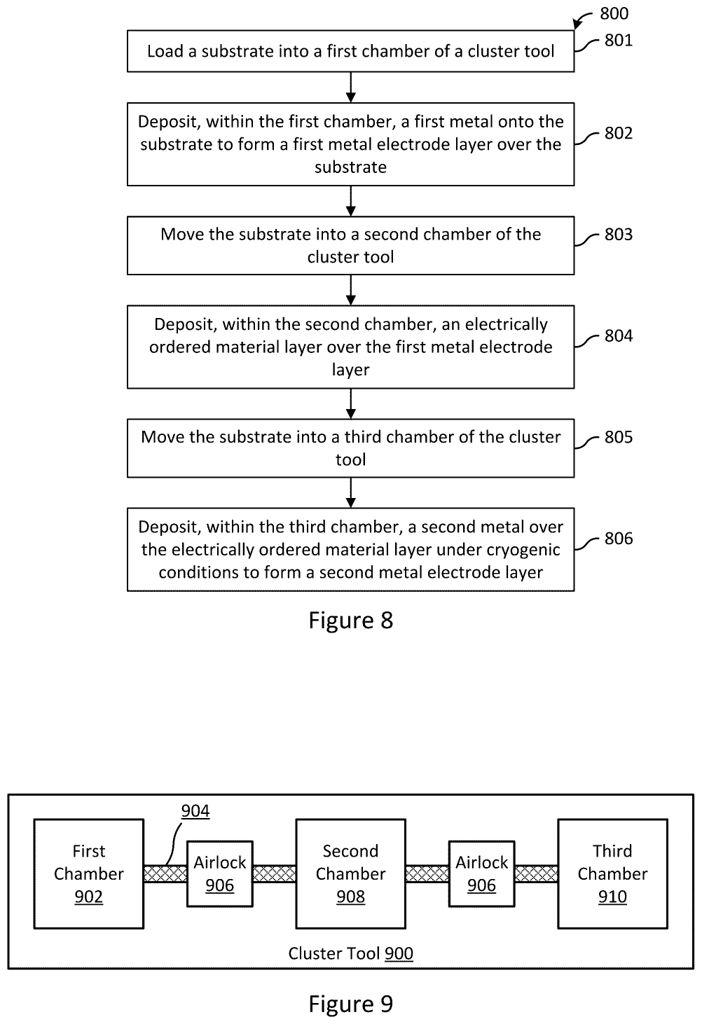

Further embodiments enable performing various of the deposition steps and processes contemplated above within a clustered system, ensuring (for example) that the workpiece 10 may be held in an inert atmosphere with rigorously controlled concentrations of impurities between deposition steps. FIG. 8 thus provides a flow chart of a method 800 for forming an electronic device using a cluster tool.

In box 801, a substrate is loaded into a first chamber of a cluster tool; in some embodiments, the substrate may be loaded over a cryogenic chuck. Next, in box 802, within the first chamber, a first metal is deposited to form a first metal electrode layer over the substrate; in some embodiments, the deposition may be performed while maintaining the cryogenic chuck at a temperature between 70 K and 170 K. In other embodiments, the temperature of the cryogenic chuck (or cooled substrate holder) may be between 70 K and 293 K.

In box 803, the substrate is moved into a second chamber of the cluster tool. In box 804, within the second chamber, an electrically ordered material layer is deposited over the first metal electrode layer.

In box 805, the substrate is moved into a third chamber of the cluster tool. In some embodiments, moving the substrate into the third chamber may further comprise moving the substrate into an intermediary chamber. In these and other embodiments, moving the substrate into the third may further comprise loading the substrate over a cryogenic chuck and depositing the second metal while maintaining the cryogenic chuck at a temperature between 70 K and 170 K. In still other embodiments, the temperature of the cryogenic chuck (or cooled substrate holder) may be between 70 K and 293 K.

In box 806, within the third chamber, a second metal is deposited over the electrically ordered material layer under cryogenic conditions to form a second metal electrode layer.

Throughout these steps, the cluster tool allows advantageously for environmentally controlled transitions between different deposition processes and environments, according to various embodiments.

FIG. 9 presents a schematic diagram of a cluster tool 900 appropriate for some embodiments of method 800. The cluster tool 900 comprises three process chambers connected by intermediary chambers and airlocks, enabling environmentally controlled transfers of a substrate 102, a workpiece 10, or any intermediate stage in formation of the workpiece 10 between the different process chambers.

The cluster tool 900 comprises a first chamber 902, which may be configured for depositing the first metal and forming the first metal electrode layer (as described in box 802 of method 800). In some embodiments, the first chamber 902 may be a PVD chamber similar to those illustrated in FIGS. 7A and 7B, with or without the cooler 710.

Connected to the first chamber 902 is an intermediary chamber 904, which connects in turn to an airlock 906 and (through subsequent connections) to the other chambers and airlocks 906 of the cluster tool 900. In various embodiments, a second chamber 908 may be configured for the deposition of the electrically ordered material layer (as described in box 804 of method 800). In some such embodiments, the second chamber 908 may be an ALD chamber similar to that illustrated in FIG. 6; in other such embodiments, the second chamber 908 may be a PVD chamber similar to those illustrated in FIG. 7, with or without the cooler 710.

Cluster tool 900 may comprise a third chamber 910, which may be configured for deposition of the second metal electrode layer under cryogenic conditions (as described in box 806 of method 800). In some embodiments the third chamber 910 may be a PVD chamber similar to those illustrated in FIGS. 7A and 7B, including the cooler 710.

In some embodiments, the first chamber 902 and the third chamber 910 may be the same chamber. (Indeed, in some embodiments, and particularly those comprising PVD for all three material layers, the first chamber 902, second chamber 908, and third chamber 910 may be the same chamber.) In certain of these embodiments, the first metal and the second metal may be the same metal; in other such embodiments, the first metal electrode layer 104 and the second metal electrode layer 108 may both be deposited under cooled or cryogenic conditions, the cooled or cryogenic conditions being the same (in some embodiments) or different (in other embodiments). Some embodiments may comprise deposition of both the first metal electrode layer 104 and the second metal electrode layer 108 from the same metal and under cooled or cryogenic conditions.

Airlocks 906 may be connected to intermediary chambers 904 between pairs of process chamber, such as the first chamber 902 and a second chamber 908. Airlocks 906 may be equipped with seals, gas inlets, and gas outlets, and may further be connected to gas lines and pumps. In various embodiments, airlocks 906 may be charged with gas or evacuated as necessary (for example) to receive a substrate 102 from the first chamber 902 and then (in another example) to prepare a resulting intermediate stage in formation of the workpiece 10 for transfer to the second chamber 908. In such embodiments, airlocks 906 protect the substrate 102 or intermediate stage in formation of the workpiece 10 by mitigating risks of damage from pressure differences between the chambers.

The arrangement of chambers in the cluster tool 900 allows for the continuous processing of substrates through the various deposition steps without exposure to external environments. This configuration enables precise control over the fabrication process, potentially leading to improved quality and consistency in the resulting electronic devices, such as the capacitor 18 of FIGS. 1C and 2C or the device 22 of FIGS. 1D and 2D.

Example embodiments of the invention are described below. Other embodiments can also be understood from the entirety of the specification as well as the claims filed herein.

### EXAMPLE 1

A method of forming an electronic device, the method including: forming a first metal electrode layer over a substrate, the first metal electrode layer including a first metal; forming an electrically ordered material layer over the first metal electrode layer; depositing a second metal over the electrically ordered material layer under cryogenic conditions to form a second metal electrode layer; and patterning the first metal electrode layer, the electrically ordered material layer, and the second metal electrode layer.

### EXAMPLE 2

The method of example 1, where forming the electrically ordered material layer further includes: depositing a material layer capable of forming an electrically ordered material; and annealing the material layer after the forming of the second metal electrode layer.

### EXAMPLE 3

The method of one of examples 1 or 2, where forming the first metal electrode layer further includes depositing the first metal over the substrate under cryogenic conditions.

### EXAMPLE 4

The method of one of examples 1 to 3, where depositing the first metal under cryogenic conditions includes loading the substrate over a cryogenic chuck disposed within a physical vapor deposition process chamber and performing a physical vapor deposition of the first metal while maintaining the cryogenic chuck at a temperature between 70 K and 170 K.

### EXAMPLE 5

The method of one of examples 1 to 4, where depositing the second metal under cryogenic conditions includes loading the substrate over a cryogenic chuck disposed within a physical vapor deposition process chamber and performing a physical vapor deposition of the second metal while maintaining the cryogenic chuck at a temperature between 70 K and 170 K.

### EXAMPLE 6

The method of one of examples 1 to 5, where the electrically ordered material layer includes a ferroelectric material layer.

### EXAMPLE 7

The method of one of examples 1 to 6, where the ferroelectric material layer includes hafnium zirconium oxide, lithium niobate, barium titanate, zinc magnesium oxide, or indium(III) selenide.

### EXAMPLE 8

The method of one of examples 1 to 7, where the ferroelectric material layer includes hafnium zirconium oxide, where the hafnium zirconium oxide is doped.

### EXAMPLE 9

The method of one of examples 1 to 8, where the electrically ordered material layer includes an antiferroelectric material layer.

### EXAMPLE 10

The method of one of examples 1 to 9, where forming the electrically ordered material layer includes performing an atomic layer deposition at temperatures between 100° C. and 400° C.

### EXAMPLE 11

The method of one of examples 1 to 10, where forming the electrically ordered material layer includes performing physical vapor deposition with the substrate disposed over a cooled chuck maintained at temperatures between 70 K and 293 K.

### EXAMPLE 12

The method of one of examples 1 to 11, where the first metal includes aluminum, titanium, molybdenum, ruthenium, tantalum, or tungsten, where the second metal includes aluminum, titanium, molybdenum, ruthenium, tantalum, or tungsten, and where the electrically ordered material layer includes hafnium zirconium oxide.

### EXAMPLE 13

The method of one of examples 1 to 12, where the first metal and the second metal are a same metal.

### EXAMPLE 14

The method of one of examples 1 to 13, where the first metal and the second metal include tungsten, and the electrically ordered material layer includes hafnium zirconium oxide.

### EXAMPLE 15

A method of forming an electronic device, the method including: forming a first metal electrode layer over a substrate, the first metal electrode layer including a first metal; forming an electrically ordered material layer over the first metal electrode layer; loading the substrate over a substrate holder disposed in a processing chamber; while cooling the substrate holder, depositing a second metal over the electrically ordered material layer to form a second metal electrode layer; and patterning the first metal electrode layer, the electrically ordered material layer, and the second metal electrode layer.

### EXAMPLE 16

The method of example 15, where the substrate holder is cooled to be between 170 K and 293 K.

### EXAMPLE 17

The method of one of examples 15 or 16, where the substrate holder is cooled to be between 125 K and 170 K.

### EXAMPLE 18

The method of one of examples 15 to 17, where forming the electrically ordered material layer includes performing an atomic layer deposition at temperatures between 100° C. and 400° C.

### EXAMPLE 19

The method of one of examples 15 to 18, where forming the electrically ordered material layer includes performing physical vapor deposition with the substrate disposed over a cooled chuck maintained at temperatures between 70 K and 293 K.

### EXAMPLE 20

A method of forming an electronic device, the method including: loading a substrate into a first chamber of a cluster tool; depositing, within the first chamber, a first metal onto the substrate to form a first metal electrode layer over the substrate; moving the substrate into a second chamber of the cluster tool; depositing, within the second chamber, an electrically ordered material layer over the first metal electrode layer; moving the substrate into a third chamber of the cluster tool; and depositing, within the third chamber, a second metal over the electrically ordered material layer under cryogenic conditions to form a second metal electrode layer.

### EXAMPLE 21

The method of example 20, where the first chamber is a physical vapor deposition chamber, where the second chamber is an atomic layer deposition chamber, and where the third chamber is a physical vapor deposition chamber.

### EXAMPLE 22

The method of one of examples 20 or 21, where moving the substrate into the third chamber includes loading the substrate over a cryogenic chuck, where depositing the second metal includes depositing the second metal while maintaining the cryogenic chuck at a temperature between 70 K and 170 K.

### EXAMPLE 23

The method of one of examples 20 to 22, where the first chamber is a physical vapor deposition chamber, where the second chamber is a physical vapor deposition chamber, and where the third chamber is a physical vapor deposition chamber.

### EXAMPLE 24

The method of one of examples 20 to 23, where the first chamber and the third chamber are a same chamber.

### EXAMPLE 25

The method of one of examples 20 to 24, where moving the substrate into the third chamber of the cluster tool includes moving the substrate into an intermediary chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming an electronic device, the method comprising:
forming a first metal electrode layer over a substrate, the first metal electrode layer comprising a first metal;
forming an electrically ordered material layer over the first metal electrode layer;
depositing a second metal over the electrically ordered material layer under cryogenic conditions to form a second metal electrode layer; and
patterning the first metal electrode layer, the electrically ordered material layer, and the second metal electrode layer.

2. The method of claim 1, wherein forming the first metal electrode layer further comprises depositing the first metal over the substrate under cryogenic conditions.

3. The method of claim 2, wherein depositing the first metal under cryogenic conditions comprises loading the substrate over a cryogenic chuck disposed within a physical vapor deposition process chamber and performing a physical vapor deposition of the first metal while maintaining the cryogenic chuck at a temperature between 70 K and 170 K.

4. The method of claim 1, wherein depositing the second metal under cryogenic conditions comprises loading the substrate over a cryogenic chuck disposed within a physical vapor deposition process chamber and performing a physical vapor deposition of the second metal while maintaining the cryogenic chuck at a temperature between 70 K and 170 K.

5. The method of claim 1, wherein the electrically ordered material layer comprises a ferroelectric material layer.

6. The method of claim 5, wherein the ferroelectric material layer comprises hafnium zirconium oxide, lithium niobate, barium titanate, zinc magnesium oxide, or indium(III) selenide.

7. The method of claim 5, wherein the ferroelectric material layer comprises hafnium zirconium oxide, wherein the hafnium zirconium oxide is doped.

8. The method of claim 1, wherein forming the electrically ordered material layer comprises performing an atomic layer deposition at temperatures between 100°C and 400°C.

9. The method of claim 1, wherein forming the electrically ordered material layer comprises performing physical vapor deposition with the substrate disposed over a cooled chuck maintained at temperatures between 70 K and 293 K.

10. The method of claim 1, wherein the first metal comprises aluminum, titanium, molybdenum, ruthenium, tantalum, or tungsten, wherein the second metal comprises aluminum, titanium, molybdenum, ruthenium, tantalum, or tungsten, and wherein the electrically ordered material layer comprises hafnium zirconium oxide.

11. The method of claim 1, wherein the first metal and the second metal comprise tungsten, and the electrically ordered material layer comprises hafnium zirconium oxide.

12. A method of forming an electronic device, the method comprising:
forming a first metal electrode layer over a substrate, the first metal electrode layer comprising a first metal;
forming an electrically ordered material layer over the first metal electrode layer;
loading the substrate over a substrate holder disposed in a processing chamber;
while cooling the substrate holder, depositing a second metal over the electrically ordered material layer to form a second metal electrode layer; and
patterning the first metal electrode layer, the electrically ordered material layer, and the second metal electrode layer.

13. The method of claim 12, wherein the substrate holder is cooled to be between 170 K and 293 K.

14. The method of claim 12, wherein the substrate holder is cooled to be between 125 K and 170 K.

15. The method of claim 12, wherein forming the electrically ordered material layer comprises performing an atomic layer deposition at temperatures between 100°C and 400°C.

16. A method of forming an electronic device, the method comprising:
loading a substrate into a first chamber of a cluster tool;
depositing, within the first chamber, a first metal onto the substrate to form a first metal electrode layer over the substrate;
moving the substrate into a second chamber of the cluster tool;
depositing, within the second chamber, an electrically ordered material layer over the first metal electrode layer;
moving the substrate into a third chamber of the cluster tool; and
depositing, within the third chamber, a second metal over the electrically ordered material layer under cryogenic conditions to form a second metal electrode layer.

17. The method of claim 16, wherein the first chamber is a physical vapor deposition chamber, wherein the second chamber is an atomic layer deposition chamber, and wherein the third chamber is a physical vapor deposition chamber.

18. The method of claim 16, wherein moving the substrate into the third chamber comprises loading the substrate over a cryogenic chuck, wherein depositing the second metal comprises depositing the second metal while maintaining the cryogenic chuck at a temperature between 70 K and 170 K.

19. The method of claim 16, wherein the first chamber is a physical vapor deposition chamber, wherein the second chamber is a physical vapor deposition chamber, and wherein the third chamber is a physical vapor deposition chamber.

20. The method of claim 16, wherein the first chamber and the third chamber are a same chamber.
